(19) United States
(12) Patent Application Publication
(10) Pub. No.: US 2024/0184968 A1
(43) Pub. Date: Jun. 6, 2024

(54) CONFIGURABLE CLOCK ENABLE AND RESET SIGNAL FOR PROGRAMMABLE LOGIC DEVICES SYSTEMS AND METHODS

(71) Applicant: Lattice Semiconductor Corporation, Hillsboro, OR (US)

(72) Inventors: Satwant Singh, Fremont, CA (US); Patrick Crotty, San Jose, CA (US)

(21) Appl. No.: 18/525,550

(22) Filed: Nov. 30, 2023

Related U.S. Application Data
(60) Provisional application No. 63/429,861, filed on Dec. 2, 2022.

(51) Int. Cl. G06F 30/347

(52) U.S. Cl. CPC G06F 30/347

(57) ABSTRACT

Various techniques are provided to efficiently implement user designs in programmable logic devices (PLDs). In one example, a PLD comprises a plurality of slices. Each slice comprises a plurality a lookup tables (LUT) and flip-flops configured to operate in response to a plurality of control signals. The PLD further comprises routing logic configured to selectively route the control signals to each of the plurality of slices. The control signals comprise at least a signal selectively configurable as a clock enable signal or a local set-reset signal. Additional systems and methods are also provided.

### CROSS-REFERENCE TO RELATED APPLICATION

This application claims priority to and the benefit of U.S. Provisional Patent Application 63/429,861 filed Dec. 2, 2022, and entitled “Configurable Clock Enable And Reset Signal For Programmable Logic Devices Systems And Methods,” which is hereby incorporated by reference in its entirety.

### TECHNICAL FIELD

The present disclosure relates to programmable logic devices (PLDs), such as field-programmable gate arrays (FPGAs), and, in particular for example, to the input/output (I/O) interfaces for such devices.

### BACKGROUND

Programmable logic devices (PLDs) (e.g., field programmable gate arrays (FPGAs), complex programmable logic devices (CPLDs), field programmable systems on a chip (FPSCs), or other types of programmable devices) may be configured with various user designs to implement desired functionality. Typically, the user designs are synthesized and mapped into configurable resources (e.g., programmable logic gates, look-up tables (LUTs), embedded hardware, or other types of resources) and interconnections available in particular PLDs. Physical placement and routing for the synthesized and mapped user designs may then be determined to generate configuration data for the particular PLDs.

Two primary types of configurable resources of a PLD include programmable logic blocks (PLBs) and routing resources. The logic blocks typically include a number of logic cells each containing a LUT and a register with some additional logic. The routing resources flexibly connect the logic blocks and/or cells to one another and can constitute greater than 65% of the area of the PLD, can consume most of the available power, and can take up most of a timing budget associated with a particular user design. In some cases, greater than 80% of the configuration bit cells (e.g., programmable memory) are used for routing. PLB utilization can be improved by increasing the amount of available routing resources, but such increases are generally more costly and consume more area.

### SUMMARY

Various techniques are disclosed to provide a configurable control signal that may be selectively implemented as a clock enable or reset signal to provide flexibility and efficiency in PLD designs. In one embodiment, a programmable logic device (PLD) comprises: a plurality of slices, each slice comprising a plurality a lookup tables (LUT) and flip-flops configured to operate in response to a plurality of control signals; routing logic configured to selectively route the control signals to each of the plurality of slices; and wherein the control signals comprise at least a signal selectively configurable as a clock enable signal or a local set-reset signal.

In another embodiment, a method comprises: receiving a design identifying operations to be performed by a programmable logic device (PLD); synthesizing the design into a plurality of PLD components, wherein the synthesizing comprises detecting a logic function operation, a ripple arithmetic operation, and/or an extended logic function operation in the design; implementing the detected operation using logic cells within a programmable logic block (PLB) of the PLD, each logic cell comprising a lookup table (LUT); placing logic cells in the PLD; and routing connections to the logic cells to pass a plurality of control signals comprising at least a signal selectively configurable as a clock enable signal or a local set-reset signal, wherein the routing comprises evaluating control signal routing scenarios including implementing control signal routing logic in the programmable logic block and implementing the control signal routing logic on the PLD for input to the programmable logic block.

In another embodiment, a non-transitory machine-readable medium storing a plurality of machine-readable instructions which when executed by one or more processors of a computer system are adapted to cause the computer system to perform a computer-implemented method comprises: receiving a design identifying operations to be performed by a programmable logic device (PLD); synthesizing the design into a plurality of PLD components, wherein the synthesizing comprises detecting a logic function operation, a ripple arithmetic operation, and/or an extended logic function operation in the design; implementing the detected operation using logic cells within a programmable logic block (PLB) of the PLD, each logic cell comprising a lookup table (LUT); placing logic cells in the PLD; and routing connections to the logic cells to pass a plurality of control signals comprising at least a signal selectively configurable as a clock enable signal or a local set-reset signal, wherein the routing comprises evaluating control signal routing scenarios including implementing control signal routing logic in the programmable logic block and implementing the control signal routing logic on the PLD for input to the programmable logic block.

### BRIEF DESCRIPTION OF THE DRAWINGS

FIG. 1 illustrates a block diagram of a programmable logic device (PLD) in accordance with an implementation of the disclosure.

FIG. 2 illustrates a block diagram of a logic block for a PLD in accordance with an implementation of the disclosure.

FIG. 3 illustrates a design process for a PLD in accordance with an implementation of the disclosure.

FIG. 4 illustrates control system routing logic for a PLD in accordance with an implementation of the disclosure.

FIG. 5 illustrates signal routing for a PLD in accordance with an implementation of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

In accordance with implementations set forth herein, techniques are provided to efficiently implement user designs in programmable logic devices (PLDs). In various implementations, a user design may be converted into and/or represented by a set of PLD components (e.g., configured for logic, arithmetic, or other hardware functions) and their associated interconnections available in a PLD. For example, a PLD may include a number of programmable logic blocks (PLBs), each PLB including a number of logic cells, and configurable routing resources that may be used to interconnect the PLBs and/or logic cells. In some implementations, each PLB may be implemented with between 2 and 16 or between 2 and 32 logic cells, for example.

In various implementations, PLB utilization in a PLD can be improved by increasing the flexibility of the PLBs, logic cells, and/or routing resources to allow for additional degrees of freedom in the routing when implementing a particular user design. Such additional degrees of freedom may allow a larger number of PLBs to be serviced by a smaller selection of routing resources, as compared to conventional PLD implementations.

In general, a PLD (e.g., an FPGA) fabric includes one or more routing structures and an array of similarly arranged logic cells arranged within programmable function blocks (e.g., PFBs and/or PLBs). One purpose of the routing structures is to programmably connect the ports of the logic cells/PLBs to one another in such combinations as desired to achieve an intended functionality. The routing structures may account for most of the area, power, and delay of the fabric. A common goal in designing a particular type of PLD is to maximize functionality while minimizing area, power, and delay of the fabric.

One approach is to increase the functionality of the logic cells and/or PLBs. There have been recent trends to go from four input look-up table structures (4-LUTs) to 6-LUTs or more as the basic function block (e.g., within a logic cell) of the fabric. A 6-LUT, for example, has two more input ports than a 4-LUT (which increases the general burden on routing) yet offers more function flexibility, thereby allowing more logic to be packed into each logic cell. In typical usage, a 6-LUT may pack 1.5× to 2× the logic capability of a 4-LUT, but it typically also consumes four times the area. Structure incorporating 6-LUT structures or more (e.g., 12-LUT structures) can provide some advantages in speed (e.g., operations completed per second), but can present a liability in overall area and power usage.

Another approach is to provide a multiple mode or convertible logic cell, where a single logic cell may be implemented with mode logic that allows the logic cell to operate according to multiple different operational or output modes. For example, such logic cell may be configured to operate according to a logic function mode, where an output of the logic cell may depend primarily on a logic function implemented within a LUT of the logic cell. Such logic cell may also be configured to operate according to a ripple arithmetic mode, where an output of the logic cell may depend on a ripple sum implemented with a LUT of the logic cell and associated carry logic configured to accept carry-in values and provide carry-out values, for example. Such logic cell may also be configured to operate as a RAM memory with independent read and write ports. Such logic cell may also be configured to operate according to an extended logic function mode, where an output of the logic cell may depend on an extended logic function implemented within multiple LUTs of multiple logic cells.

In some implementations, a logic cell may be implemented with a separate extended logic or “OFX” output port and a separate function and/or sum or “FS” output port. “F” may be the direct output of the 4-LUT in logic function mode. “S” may the SUM in ripple arithmetic mode that uses the LUT (with generate and propagate registers and/or signals) along with carry logic downstream of the LUT. There may also be a separate and/or interconnected register output “Q” for each LUT and/or logic cell.

Multiple logic cells, which in some implementations may be adjacent logic cells arranged in a PLB, may be arranged in interconnected groups sometimes referred to as slices. Interconnections between logic cells in a slice may be hardwired, for example, may be programmably implemented with routing resources, or may be implemented with a combination of hardwired and configurable routing resources. Slices may include two, three, four, or more logic cells, for example, and one or more slices may be implemented entirely or partially within a PLB.

In various implementations, slices including multiple mode or convertible logic cells may be implemented with inputs and outputs sufficient to allow two logic cells with constituent n-LUTs to be operated together to provide a higher order LUT (e.g., an (n+1)-LUT). In implementations where the slice consists of two multiple mode logic cells implemented with separate OFX and FS ports, the OFX port of the first logic cell may be referred to as OFX0 and the OFX port of the second logic cell as OFX1, and similarly with the FS0 and FS1 ports.

For example, in implementations where the two multiple mode logic cells in the slice each include a 4-LUT, the OFX0 output signal corresponds to the two 4-LUT output signals combined with a 2:1 multiplexer (mux) to make a 5-LUT, where the select port of the 2:1 mux corresponds to the fifth LUT input of the 5-LUT (e.g., designated MO, as described herein). In various implementations, the OFX1 output signal provides a means for creating higher order LUTs (e.g., 6-LUTs, 7-LUTs, and/or higher order LUTs) in a similar way. One can combine two 5-LUTs to make a 6-LUT, or combine two 6-LUTs to make a 7-LUT for example.

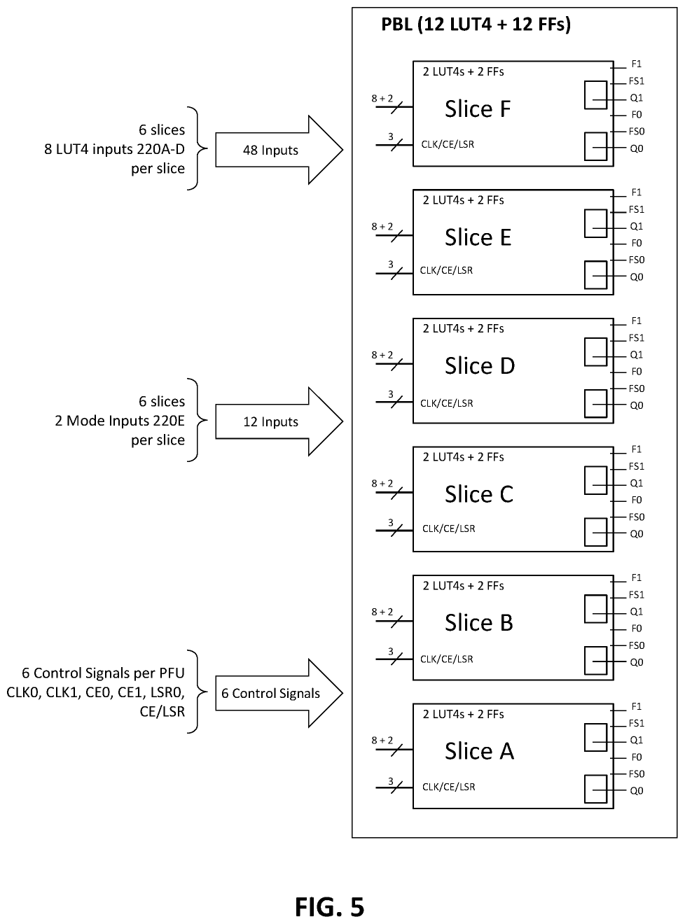

In such slice implementations, for example, there may be six outputs (e.g., F1, FS1, Q1, F0, FS0, Q0, as illustrated in FIG. 5) from each slice to the routing resources. This has the benefit of offering the capability of higher order LUTs, but includes the disadvantage of additional ports (e.g., relative to logic cells with FS ports only), which are a greater burden on the routing resources.

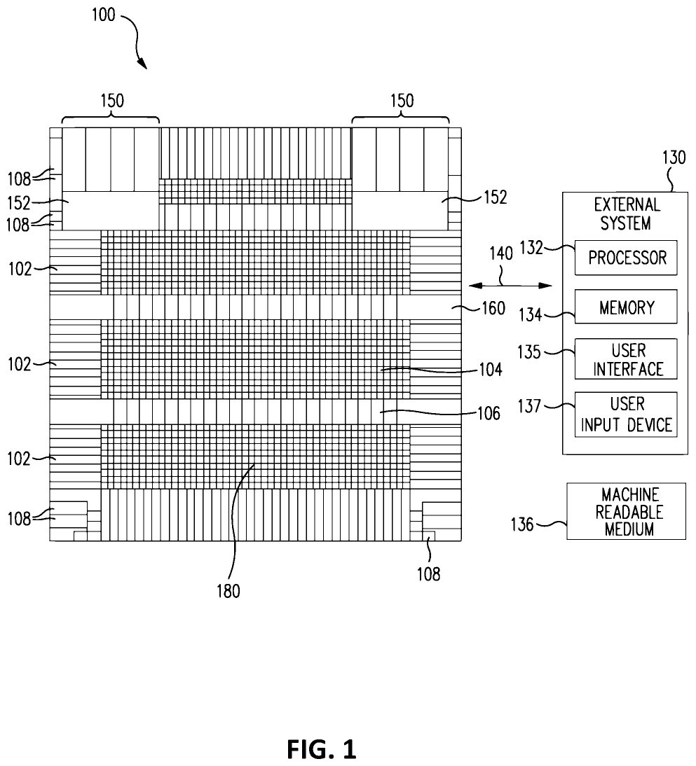

Referring now to the drawings, FIG. 1 illustrates a block diagram of a PLD 100 in accordance with an implementation of the disclosure. PLD 100 (e.g., a field programmable gate array (FPGA)), a complex programmable logic device (CPLD), a field programmable system on a chip (FPSC), or other type of programmable device) generally includes input/output (I/O) blocks 102 and logic blocks 104 (e.g., also referred to as programmable logic blocks (PLBs), programmable functional units (PFUs), or programmable logic cells (PLCs)).

I/O blocks 102 provide I/O functionality (e.g., to support one or more I/O and/or memory interface standards) for PLD 100, while programmable logic blocks 104 provide logic functionality (e.g., LUT-based logic or logic gate array-based logic) for PLD 100. Additional I/O functionality may be provided by serializer/deserializer (SERDES) blocks 150 and physical coding sublayer (PCS) blocks 152. PLD 100 may also include hard intellectual property core (IP) blocks 160 to provide additional functionality (e.g., substantially predetermined functionality provided in hardware which may be configured with less programming than logic blocks 104).

PLD 100 may also include blocks of memory 106 (e.g., blocks of EEPROM, block SRAM, and/or flash memory), clock-related circuitry 108 (e.g., clock sources, PLL circuits, and/or DLL circuits), and/or various routing resources 180 (e.g., interconnect and appropriate switching logic to provide paths for routing signals throughout PLD 100, such as for clock signals, data signals, or others) as appropriate. In general, the various elements of PLD 100 may be used to perform their intended functions for desired applications, as would be understood by one skilled in the art.

For example, certain I/O blocks 102 may be used for programming memory 106 or transferring information (e.g., various types of user data and/or control signals) to/from PLD 100. Other I/O blocks 102 include a first programming port (which may represent a central processing unit (CPU) port, a peripheral data port, an SPI interface, and/or a sysCONFIG programming port) and/or a second programming port such as a joint test action group (JTAG) port (e.g., by employing standards such as Institute of Electrical and Electronics Engineers (IEEE) 1149.1 or 1532 standards). In various implementations, I/O blocks 102 may be included to receive configuration data and commands (e.g., over one or more connections 140) to configure PLD 100 for its intended use and to support serial or parallel device configuration and information transfer with SERDES blocks 150, PCS blocks 152, hard IP blocks 160, and/or logic blocks 104 as appropriate.

It should be understood that the number and placement of the various elements are not limiting and may depend upon the desired application. For example, various elements may not be required for a desired application or design specification (e.g., for the type of programmable device selected).

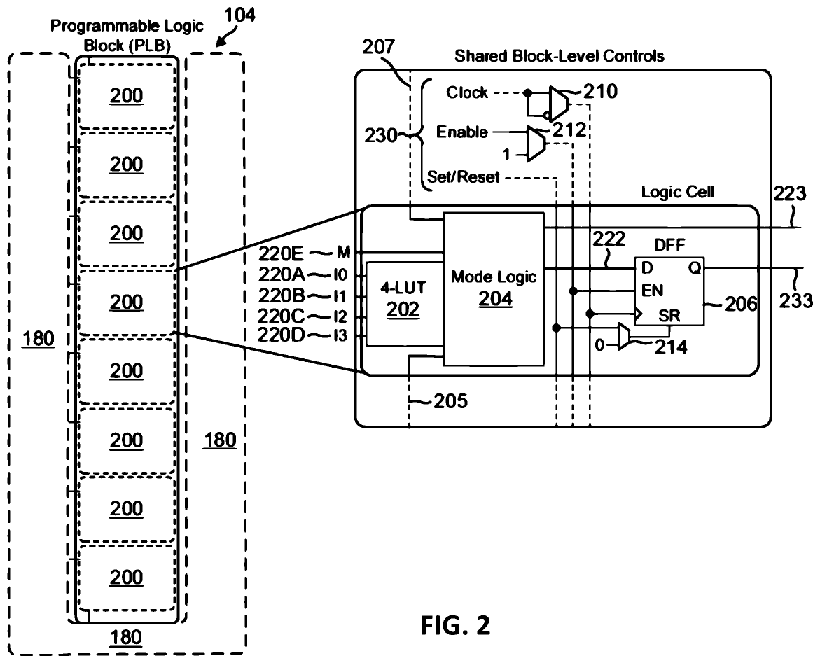

Furthermore, it should be understood that the elements are illustrated in block form for clarity and that various elements would typically be distributed throughout PLD 100, such as in and between logic blocks 104, hard IP blocks 160, and routing resources (e.g., routing resources 180 of FIG. 2) to perform their conventional functions (e.g., storing configuration data that configures PLD 100 or providing interconnect structure within PLD 100). It should also be understood that the various implementations disclosed herein are not limited to programmable logic devices, such as PLD 100, and may be applied to various other types of programmable devices, as would be understood by one skilled in the art.

An external system 130 may be used to create a desired user configuration or design of PLD 100 and generate corresponding configuration data to program (e.g., configure) PLD 100. For example, system 130 may provide such configuration data to one or more I/O blocks 102, SERDES blocks 150, and/or other portions of PLD 100. As a result, programmable logic blocks 104, various routing resources, and any other appropriate components of PLD 100 may be configured to operate in accordance with user-specified applications.

In the illustrated implementation, system 130 is implemented as a computer system. In this regard, system 130 includes, for example, one or more processors 132 which may be configured to execute instructions, such as software instructions, provided in one or more memories 134 and/or stored in non-transitory form in one or more non-transitory machine-readable mediums 136 (e.g., which may be internal or external to system 130). For example, in some implementations, system 130 may run PLD configuration software, such as Lattice Diamond System Planner software available from Lattice Semiconductor Corporation to permit a user to create a desired configuration and generate corresponding configuration data to program PLD 100.

System 130 also includes, for example, a user interface 135 (e.g., a screen or display) to display information to a user, and one or more user input devices 137 (e.g., a keyboard, mouse, trackball, touchscreen, and/or other device) to receive user commands or design entry to prepare a desired configuration of PLD 100.

FIG. 2 illustrates a block diagram of a logic block 104 of PLD 100 in accordance with an implementation of the disclosure. As discussed, PLD 100 includes a plurality of logic blocks 104 including various components to provide logic and arithmetic functionality.

In the example implementation shown in FIG. 2, logic block 104 includes a plurality of logic cells 200, which may be interconnected internally within logic block 104 and/or externally using routing resources 180. For example, each logic cell 200 may include various components such as: a lookup table (LUT) 202, a mode logic circuit 204, a register 206 (e.g., a flip-flop or latch), and various programmable multiplexers (e.g., programmable multiplexers 212 and 214) for selecting desired signal paths for logic cell 200 and/or between logic cells 200. In this example, LUT 202 accepts four inputs 220A-220D, which makes it a four-input LUT (which may be abbreviated as “4-LUT” or “LUT4”) that can be programmed by configuration data for PLD 100 to implement any appropriate logic operation having four inputs or less. Mode Logic 204 may include various logic elements and/or additional inputs, such as input 220E, to support the functionality of the various modes, as described herein. LUT 202 in other examples may be of any other suitable size having any other suitable number of inputs for a particular implementation of a PLD. In some implementations, different size LUTs may be provided for different logic blocks 104 and/or different logic cells 200.

An output signal 222 from LUT 202 and/or mode logic 204 may in some implementations be passed through register 206 to provide an output signal 233 of logic cell 200. In various implementations, an output signal 223 from LUT 202 and/or mode logic 204 may be passed to output 223 directly, as shown. Depending on the configuration of multiplexers 210-214 and/or mode logic 204, output signal 222 may be temporarily stored (e.g., latched) in latch 206 according to control signals 230. In some implementations, configuration data for PLD 100 may configure output 223 and/or 233 of logic cell 200 to be provided as one or more inputs of another logic cell 200 (e.g., in another logic block or the same logic block) in a staged or cascaded arrangement (e.g., comprising multiple levels) to configure logic operations that cannot be implemented in a single logic cell 200 (e.g., logic operations that have too many inputs to be implemented by a single LUT 202). Moreover, logic cells 200 may be implemented with multiple outputs and/or interconnections to facilitate selectable modes of operation.

Mode logic circuit 204 may be utilized for some configurations of PLD 100 to efficiently implement arithmetic operations such as adders, subtractors, comparators, counters, or other operations, to efficiently form some extended logic operations (e.g., higher order LUTs, working on multiple bit data), to efficiently implement a relatively small RAM, and/or to allow for selection between logic, arithmetic, extended logic, and/or other selectable modes of operation. In this regard, mode logic circuits 204, across multiple logic cells 202, may be chained together to pass carry-in signals 205 and carry-out signals 207, and/or other signals (e.g., output signals 222) between adjacent logic cells 202, as described herein. In the example of FIG. 2, carry-in signal 205 may be passed directly to mode logic circuit 204, for example, or may be passed to mode logic circuit 204 by configuring one or more programmable multiplexers, as described herein. In some implementations, mode logic circuits 204 may be chained across multiple logic blocks 104.

Logic cell 200 illustrated in FIG. 2 is merely an example, and logic cells 200 according to different implementations may include different combinations and arrangements of PLD components. Also, although FIG. 2 illustrates logic block 104 having eight logic cells 200, logic block 104 according to other implementations may include fewer logic cells 200 or more logic cells 200. Each of the logic cells 200 of logic block 104 may be used to implement a portion of a user design implemented by PLD 100. In this regard, PLD 100 may include many logic blocks 104, each of which may include logic cells 200 and/or other components which are used to collectively implement the user design.

Portions of a user design may be adjusted to occupy fewer logic cells 200, fewer logic blocks 104, and/or with less burden on routing resources 180 when PLD 100 is configured to implement the user design. Such adjustments according to various implementations may identify certain logic, arithmetic, and/or extended logic operations, to be implemented in an arrangement occupying multiple implementations of logic cells 200 and/or logic blocks 104. An optimization process may route various signal connections associated with the arithmetic/logic operations such that a logic, ripple arithmetic, or extended logic operation may be implemented into one or more logic cells 200 and/or logic blocks 104 to be associated with the preceding arithmetic/logic operations.

It has been observed that not all signal paths (e.g., control signals 230, including clock signal, enable signal, and set/reset signal) are required at the shared block level and may be selectively allocated as described herein. Various implementations of selective allocation approaches may be used to reduce the size and cost of a PLD without negatively impacting performance goals. For example, the following Table 1 illustrates utilization rates of various configurable control signal paths (e.g., clock, clock enable, and set/reset signals of control signals 230) in an example PLD design:

TABLE 1

| | | | | Percentage |
|---|---|---|---|---|
| CLK | CE | LSR | Comments | of Logic Cells |
| YES | YES | YES | All three used | 7% |
| YES | YES | — | No LSR used | 46% |
| YES | — | YES | No CE used | 12% |
| YES | — | — | No CE or LSR used | 35% |

In the example set forth in Table 1, it was observed that a clock signal, CLK, is typically used, but 81 percent of flip-flops have no LSR utilization (only 19% did in the example design), while 47 percent of flip-flops have no clock enable, CE. In view of these and related observations, systems and methods are described herein to improve design efficiency of register control signal utilization and routing.

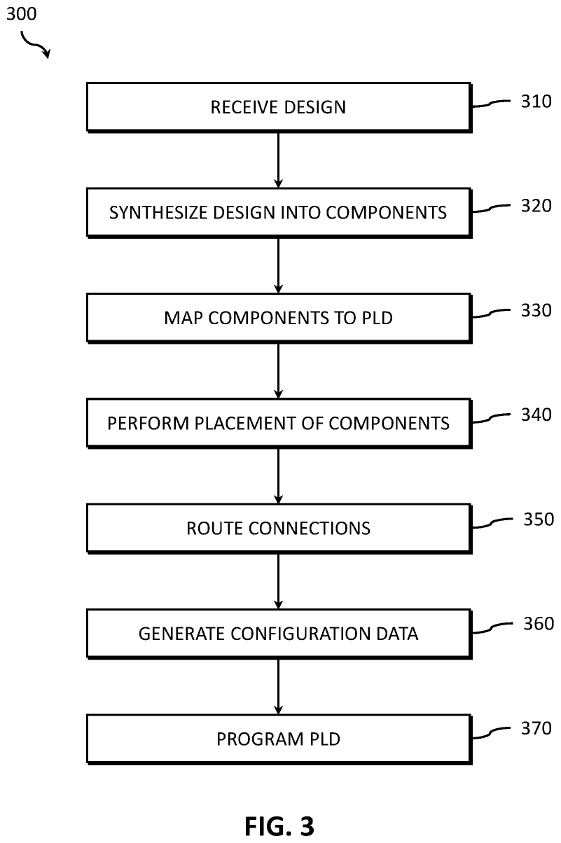

FIG. 3 illustrates a design process 300 for a PLD in accordance with an implementation of the disclosure. For example, the process of FIG. 3 may be performed by system 130 running Lattice Diamond software to configure PLD 100. In some implementations, the various files and information referenced in FIG. 3 may be stored, for example, in one or more databases and/or other data structures in memory 134, machine readable medium 136, and/or otherwise.

In operation 310, system 130 receives a user design that specifies the desired functionality of PLD 100. For example, the user may interact with system 130 (e.g., through user input device 137 and hardware description language (HDL) code representing the design) to identify various features of the user design (e.g., high level logic operations, hardware configurations, and/or other features). In some implementations, the user design may be provided in a register transfer level (RTL) description (e.g., a gate level description). System 130 may perform one or more rule checks to confirm that the user design describes a valid configuration of PLD 100. For example, system 130 may reject invalid configurations and/or request the user to provide new design information as appropriate.

In operation 320, system 130 synthesizes the design to create a netlist (e.g., a synthesized RTL description) identifying an abstract logic implementation of the user design as a plurality of logic components (e.g., also referred to as netlist components). In some implementations, the netlist may be stored in Electronic Design Interchange Format (EDIF) in a Native Generic Database (NGD) file.

In some implementations, synthesizing the design into a netlist in operation 320 may involve converting (e.g., translating) the high-level description of logic operations, hardware configurations, and/or other features in the user design into a set of PLD components (e.g., logic blocks 104, logic cells 200, and other components of PLD 100 configured for logic, arithmetic, or other hardware functions to implement the user design) and their associated interconnections or signals. Depending on implementations, the converted user design may be represented as a netlist.

In some implementations, synthesizing the design into a netlist in operation 320 may further involve performing an optimization process on the user design (e.g., the user design converted/translated into a set of PLD components and their associated interconnections or signals) to reduce propagation delays, consumption of PLD resources and routing resources, and/or otherwise optimize the performance of the PLD when configured to implement the user design. Depending on implementations, the optimization process may be performed on a netlist representing the converted/translated user design. Depending on implementations, the optimization process may represent the optimized user design in a netlist (e.g., to produce an optimized netlist).

In some implementations, the optimization process may include optimizing certain instances of a logic function operation, a ripple arithmetic operation, and/or an extended logic function operation which, when a PLD is configured to implement the user design, would occupy a plurality of configurable PLD components (e.g., logic cells 200, logic blocks 104, and/or routing resources 180). For example, the optimization process may include detecting multiple mode or configurable logic cells implementing logic function operations, ripple arithmetic operations, extended logic function operations, and/or corresponding routing resources in the user design, interchanging operational modes of logic cells implementing the various operations to reduce the number of PLD components and/or routing resources used to implement the operations and/or to reduce the propagation delay associated with the operations, and/or reprogramming corresponding LUTs and/or mode logic to account for the interchanged operational modes.

In another example, the optimization process may include detecting extended logic function operations and/or corresponding routing resources in the user design, implementing the extended logic operations into multiple mode or convertible logic cells with single physical logic cell outputs, routing or coupling the logic cell outputs of a first set of logic cells to the inputs of a second set of logic cells to reduce the number of PLD components used to implement the extended logic operations and/or routing resources and/or to reduce the propagation delay associated with the extended logic operations, and/or programming corresponding LUTs and/or mode logic to implement the extended logic function operations with at least the first and second sets of logic cells.

In another example, the optimization process may include detecting multiple mode or configurable logic cells implementing logic function operations, ripple arithmetic operations, extended logic function operations, and/or corresponding routing resources in the user design, interchanging operational modes of logic cells implementing the various operations to provide a programmable register along a signal path within the PLD to reduce propagation delay associated with the signal path, and reprogramming corresponding LUTs, mode logic, and/or other logic cell control bits/registers to account for the interchanged operational modes and/or to program the programmable register to store or latch a signal on the signal path.

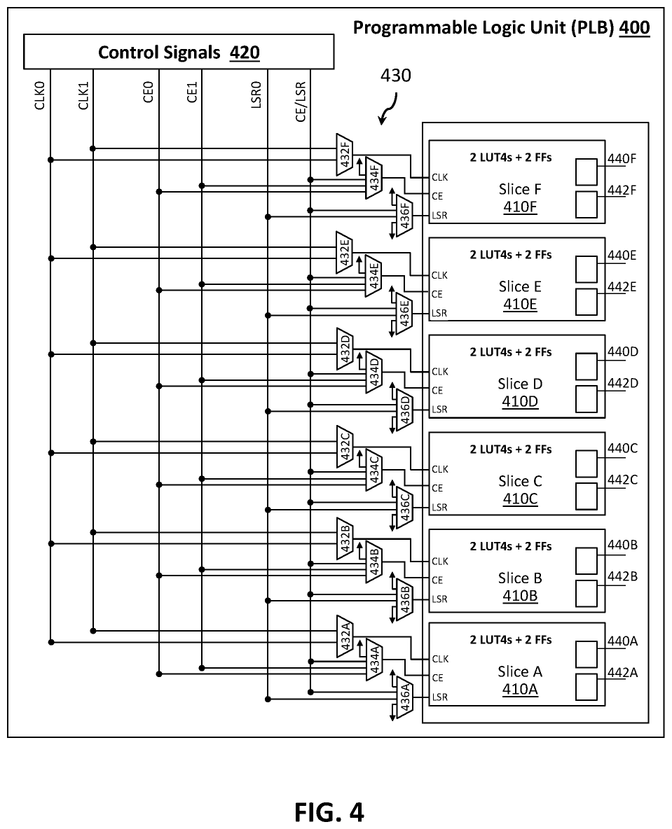

In some implementations, the optimization process may include optimization of control signal paths as described herein (e.g., as illustrated in FIG. 4). For example, the routing of control signals 230 may be located in individual logic cells as illustrated in FIG. 2 (see, e.g., MUX 210, MUX 212, and MUX 214). In some designs, an optimization of the control signal paths may be achieved by moving the routing logic outside of the logic cells on the PLB in a generalized control signal arrangement, for example, as described herein in FIG. 4, to reduce the number of system components, reduce the size of the of the FPGA and/or provide other advantages.

In operation 330, system 130 performs a mapping process that identifies components of PLD 100 that may be used to implement the user design. In this regard, system 130 may map the optimized netlist (e.g., stored in operation 320 as a result of the optimization process) to various types of components provided by PLD 100 (e.g., logic blocks 104, logic cells 200, embedded hardware, and/or other portions of PLD 100) and their associated signals (e.g., in a logical fashion, but without yet specifying placement or routing). In some implementations, the mapping may be performed on one or more previously-stored NGD files, with the mapping results stored as a physical design file (e.g., also referred to as an NCD file). In some implementations, the mapping process may be performed as part of the synthesis process in operation 320 to produce a netlist that is mapped to PLD components.

In operation 340, system 130 performs a placement process to assign the mapped netlist components to particular physical components residing at specific physical locations of the PLD 100 (e.g., assigned to particular logic cells 200, logic blocks 104, routing resources 180, and/or other physical components of PLD 100), and thus determine a layout for the PLD 100. In some implementations, the placement may be performed on one or more previously-stored NCD files, with the placement results stored as another physical design file.

In operation 350, system 130 performs a routing process to route connections (e.g., using routing resources 180) among the components of PLD 100 based on the placement layout determined in operation 340 to realize the physical interconnections among the placed components. In some implementations, the routing may be performed on one or more previously-stored NCD files, with the routing results stored as another physical design file.

In various implementations, routing the connections in operation 350 may further involve performing an optimization process on the user design to reduce propagation delays, consumption of PLD resources and/or routing resources, and/or otherwise optimize the performance of the PLD when configured to implement the user design. The optimization process may in some implementations be performed on a physical design file representing the converted/translated user design, and the optimization process may represent the optimized user design in the physical design file (e.g., to produce an optimized physical design file).

In some implementations, the optimization process may include optimizing certain instances of a logic function operation, a ripple arithmetic operation, and/or an extended logic function operation which, when a PLD is configured to implement the user design, would occupy a plurality of configurable PLD components (e.g., logic cells 200, logic blocks 104, and/or routing resources 180). For example, the optimization process may include detecting multiple mode or configurable logic cells implementing logic function operations, ripple arithmetic operations, extended logic function operations, and/or corresponding routing resources in the user design, interchanging operational modes of logic cells implementing the various operations to reduce the number of PLD components and/or routing resources used to implement the operations and/or to reduce the propagation delay associated with the operations, and/or reprogramming corresponding LUTs and/or mode logic to account for the interchanged operational modes.

In another example, the optimization process may include detecting extended logic function operations and/or corresponding routing resources in the user design, implementing the extended logic operations into multiple mode or convertible logic cells with single physical logic cell outputs, routing or coupling the logic cell outputs of a first set of logic cells to the inputs of a second set of logic cells to reduce the number of PLD components used to implement the extended logic operations and/or routing resources and/or to reduce the propagation delay associated with the extended logic operations, and/or programming corresponding LUTs and/or mode logic to implement the extended logic function operations with at least the first and second sets of logic cells.

In another example, the optimization process may include detecting multiple mode or configurable logic cells implementing logic function operations, ripple arithmetic operations, extended logic function operations, and/or corresponding routing resources in the user design, interchanging operational modes of logic cells implementing the various operations to provide a programmable register along a signal path within the PLD to reduce propagation delay associated with the signal path, and reprogramming corresponding LUTs, mode logic, and/or other logic cell control bits/registers to account for the interchanged operational modes and/or to program the programmable register to store or latch a signal on the signal path.

Changes in the routing may be propagated back to prior operations, such as synthesis, mapping, and/or placement, to further optimize various aspects of the user design. In some implementations, when routing the connections in operation 350, the multiplexers of FIG. 4 are programmed to selectively route the control signals as described herein.

In various implementations, routing the connections in operation 350 may further involve performing an optimization process on control signal routing to reduce propagation delays, consumption of PLD resources and/or routing resources, and/or otherwise optimize the performance of the PLD when configured to implement the user design. In some implementations, the optimization process may include an analysis of control signal usage across logic cells and a generalization of routing logic outside of the logic cell as described herein (e.g., as illustrated in FIG. 4).

Thus, following operation 350, one or more physical design files may be provided which specify the user design after it has been synthesized (e.g., converted and optimized), mapped, placed, and routed (e.g., further optimized) for PLD 100 (e.g., by combining the results of the corresponding previous operations). In operation 360, system 130 generates configuration data for the synthesized, mapped, placed, and routed user design. In operation 370, system 130 configures PLD 100 with the configuration data by, for example, loading a configuration data bitstream into PLD 100 over connection 140.

FIG. 4 shows a block diagram illustrating control signals for a programmable logic block (PLB) 400 or programmable functional unit (PFU), according to one or more implementations of the present disclosure. The PLB 400 includes a plurality of slices 410A-F, each of which includes two lookup tables (LUTs) and two flip-flops (FF), for a total of 12 LUTs and 12 FFs. Other arrangements may also be used in accordance with the teachings of the present disclosure, including fewer or more slices, LUTs, and/or FFs. In the illustrated implementation, the control signal routing of the conventional approach (e.g., control signals 230 and MUXs 210, 212, and 214 as illustrated in FIG. 2) are replaced with routing logic placed on the PLB outside of the slices 410A-F.

As illustrated, each slice 410A-F includes configurable clock (CLK), local set/reset (LSR), and clock enable signal inputs. In various implementations, the control signals 420 may be received by PLB 400 and routed to the routing logic 430 through appropriate circuitry and components such as one or more multiplexers and/or inverters. The control signals 420 are then routed to the control signal inputs of each slice 410A-F through the routing logic 430, which may include, for example, a plurality of multiplexers 432A-F, 434A-F, and 436A-F, allowing for configurable control signal inputs to each slice 410A-F.

In the illustrated implementation, the control signals 420 include two clock signals (CLK0 and CLK1), two clock enable signals (CE0 and CE1), one local set/reset signal (LSRO), and one configurable clock enable/local set-reset signal (CE/LSR). In operation, the LSR signal is used to selectively clear and set the flip-flops in a slice. The clock signal provides synchronization and the clock enable signal is used to control writing to the registers of the slices. For example, when the clock enable signal is low, data in a register (e.g., flip-flop) of the slice is maintained. When the clock enable signal is high, new data is written into the register.

As illustrated, the PLB 400 includes routing logic 430 that multiplexes the control signals 420 for input to each slice 410A-F. Each slice includes (i) a first multiplexer 432A-F configured to select between the first clock signal, CLK0, and the second clock signal, CLK1, (ii) a second multiplexer 434A-F configured to select between the first clock enable signal, CE0, the second clock enable signal, CE1, and the CE/LSR signal, and (iii) a third multiplexer 436A-F configured to select between the first set/reset signal, LSRO, and the configurable signal CE/LSR. Thus, the control signals 420 are input to each slice 410A-F as configured by the multiplexers 432A-F, 434A-F, and 436A-F.

Each slice 410A-F has one or more output signals, illustrated by output signals 440A-F and/or 442A-F, respectively. The output signals 440A-F and 442A-F may represent the output signals from each of the two 4-bit binary lookup tables (LUT4s) or other output signals (e.g., mode logic) depending on the implementation. Depending on the configuration of multiplexers 432A-F, 434A-F, and 436A-F, the output signals of a slice 410A-F may be temporarily stored in a latch (e.g., latch 206 of FIG. 2) according to control signals 420 received at the CLK, CE, and LSR inputs of each slice 410A-F. In some implementations, the output signals 440A-F may be configured as one or more inputs of another logic cell (e.g., in another logic block or the same logic block) in a staged or cascaded arrangement (e.g., comprising multiple levels) to configure logic operations that cannot be implemented in a single logic cell (e.g., logic operations that have too many inputs to be implemented by the 2 LUT4s).

In operation, each clock signal CLK0 and CLK1 is routed to the multiplexers 432A-F, which is configured to select one of the clock signals for input, CLK, to each respective slice. In various implementations, the clock signal CLK provides synchronization of the slices 410A-F. Each clock enable signal CE0 and CE1 is routed to the multiplexers 434A-F, which is configured to select one of the clock enable signals for input, CE, to each respective slice 410A-F. Generally, when the clock enable signal CE is low data in the flip-flops is latched, and when the clock enable signal CE is high, the data may be written to the flip-flops. The local set/reset signal LSRO is routed to multiplexers 436A-F, which are configured to select the set/reset signal for input, LSR, to each respective slice to selectively clear the flip-flops. A sixth input signal, CE/LSR may also be configured to provide an additional clock enable signal or local set/reset signal which is input to the multiplexers 434A-F and 436A-F, providing additional control signal configurations for the clock enable CE and local set-reset LSR inputs to each slice 410A-F.

The illustrated implementation provides numerous advantages over conventional approaches. The illustrated implementation provides configurable set/reset and clock enable control signals to the programmable functional unit, reducing the components and control signal lines in the PLB. It has been observed that in various designs not all of the control signals are needed in a logic cell, and thus cost and size savings are achieved by removing unnecessary routing paths and components. For example, it is observed in an example design that 81% of the flip-flops had no LSR, and 47% had no clock enable. Further, the present disclosure proposed moving control signal routing logic from the slices to the PLB, providing a local tie that simplifies SW routing.

Referring to FIGS. 2 and 5, in one implementation a PLB includes six slices, Slices A-F, with each slice having two LUT4s and 2 flip-flops. This PLB uses 48 inputs, including the 8 LUT4 inputs 220A-D per slice, and 12 mode inputs, including 2 mode inputs 220E per slice. As shown in the implementation of FIG. 2, each logic cell includes three control signals (a clock signal CK, a clock enable signal CE, and a local set/reset signal LSR) per slice. As illustrated in FIG. 5, the implementation of FIG. 4 moves the routing configuration components out of the logic cell and may be implemented with six control signals. In various implementations, a PBL may include different size LUTs and may be implemented other suitable numbers of inputs than described in the illustrated implementation.

Where applicable, various implementations provided by the present disclosure can be implemented using hardware, software, or combinations of hardware and software. Also, where applicable, the various hardware components and/or software components set forth herein can be combined into composite components comprising software, hardware, and/or both without departing from the spirit of the present disclosure. Where applicable, the various hardware components and/or software components set forth herein can be separated into sub-components comprising software, hardware, or both without departing from the spirit of the present disclosure. In addition, where applicable, it is contemplated that software components can be implemented as hardware components, and vice-versa.

In this regard, various implementations described herein may be implemented with various types of hardware and/or software and allow for significant improvements in, for example, performance and space utilization.

Software in accordance with the present disclosure, such as program code and/or data, can be stored on one or more non-transitory machine-readable mediums. It is also contemplated that software identified herein can be implemented using one or more general purpose or specific purpose computers and/or computer systems, networked and/or otherwise. Where applicable, the ordering of various steps described herein can be changed, combined into composite steps, and/or separated into sub-steps to provide features described herein.

Embodiments described above illustrate but do not limit the invention. It should also be understood that numerous modifications and variations are possible in accordance with the principles of the present invention. Accordingly, the scope of the invention is defined only by the following claims.

What is claimed is:

1. A programmable logic device (PLD) comprising:
a plurality of slices, each slice comprising a plurality a lookup tables (LUT) and flip-flops configured to operate in response to a plurality of control signals;
routing logic configured to selectively route the control signals to each of the plurality of slices; and
wherein the control signals comprise at least a signal selectively configurable as a clock enable signal or a local set-reset signal.

2. The PLD of claim 1, wherein each LUT is a four input LUT (4-LUT).

3. The PLD of claim 1, wherein the plurality of control signals comprises a plurality of clock signals, and wherein the routing logic comprises multiplexing circuitry configured to selectively route the clock signals to each of the plurality of slices as a clock input.

4. The PLD of claim 1, wherein the plurality of control signals comprises a plurality of clock enable signals, and wherein the routing logic comprises multiplexing circuitry configured to selectively route the clock enable signals to each of the plurality of slices as a clock enable input.

5. The PLD of claim 4, wherein the plurality of control signals further comprises a control signal configurable for routing as a clock enable signal and/or local set-reset (LSR) signal.

6. The PLD of claim 1, wherein the plurality of control signals comprises at least one local set-reset signal, and wherein the routing logic comprises multiplexing circuitry configured to selectively route the local set-reset signal to each of the plurality of slices as a local set-reset signal input.

7. The PLD of claim 1, wherein the control signals comprise at least a first clock signal, a second clock signal, a first clock enable signal, a second clock enable signal, a first local set-reset signal, and the configurable signal.

8. The PLD of claim 7, wherein the routing logic selectively routes one of the clock signals, one of the clock enable signals, and one of the local set-reset signals to each of the slices.

9. The PLD of claim 8, wherein the slices are configured to route each of the received control signals to one or more of the flip-flops on a corresponding control signal path without further multiplexing and/or routing logic.

10. The PLD of claim 8, wherein a plurality of slice are clocked by the same clock signal.

11. A method for programming the PLD of claim 1, comprising:
generating configuration data to configure the routing logic of the PLD in accordance with a synthesized design; and programming the PLD with the configuration data.

12. A method comprising:
receiving a design identifying operations to be performed by a programmable logic device (PLD);
synthesizing the design into a plurality of PLD components, wherein the synthesizing comprises detecting a logic function operation, a ripple arithmetic operation, and/or an extended logic function operation in the design;
implementing the detected operation using logic cells within a programmable logic block (PLB) of the PLD, each logic cell comprising a lookup table (LUT);
placing logic cells in the PLD; and
routing connections to the logic cells to pass a plurality of control signals comprising at least a signal selectively configurable as a clock enable signal or a local set-reset signal, wherein the routing comprises evaluating control signal routing scenarios including implementing control signal routing logic in the programmable logic block and implementing the control signal routing logic on the PLD for input to the programmable logic block.

13. The method of claim 12, comprising:
configuring routing logic on the PLD to receive a plurality of control signals and selectively route the control signals to the PLB.

14. The method of claim 12, wherein routing connections further comprises routing a plurality of clock signals to the routing logic; and
wherein the routing logic includes multiplexing circuitry configured to selectively route the clock signals to the PLD as a clock input.

15. The method of claim 12, wherein routing connections further comprises routing a plurality of clock enable signals to the routing logic; and
wherein the routing logic includes multiplexing circuitry configured to selectively route the clock enable signals to the PLD as a clock enable input.

16. The method of claim 12, wherein routing connections further comprises defining a configurable control signal path; and
wherein the routing logic is configurable to receive a clock enable signal and/or a local set-reset (LSR) signal from the configurable control signal path and selectively route the received signal to a clock enable input or local set-reset input of the PLB.

17. The method of claim 12, wherein routing connections further comprises routing at least one local set-reset signal to the routing logic; and
wherein the routing logic includes multiplexing circuitry configured to selectively route the at least one local set-reset signal to the PLD as an LSR input.

18. The method of claim 12, wherein routing connections further comprises routing at least a first clock signal, a second clock signal, a first clock enable signal, a second clock enable signal, a first local set-reset signal, and the configurable signal.

19. The method of claim 18, wherein the routing connections further comprises routing one of the clock signals, one of the clock enable signals, and one of the local set-reset signals to the PLB.

20. A non-transitory machine-readable medium storing a plurality of machine-readable instructions which when executed by one or more processors of a computer system are adapted to cause the computer system to perform a computer-implemented method comprising:
receiving a design identifying operations to be performed by a programmable logic device (PLD);
synthesizing the design into a plurality of PLD components, wherein the synthesizing comprises detecting a logic function operation, a ripple arithmetic operation, and/or an extended logic function operation in the design;
implementing the detected operation using logic cells within a programmable logic block (PLB) of the PLD, each logic cell comprising a lookup table (LUT);
placing logic cells in the PLD; and
routing connections to the logic cells to pass a plurality of control signals comprising at least a signal selectively configurable as a clock enable signal or a local set-reset signal, wherein the routing comprises evaluating control signal routing scenarios including implementing control signal routing logic in the programmable logic block and implementing the control signal routing logic on the PLD for input to the programmable logic block.
